(19) United States
(12) Patent Application Publication
(10) Pub. No.: US 2015/0187921 A1
(43) Pub. Date: Jul. 2, 2015

(54) POWER SEMICONDUCTOR DEVICE

(71) Applicant: SAMSUNG ELECTRO-MECHANICS CO., LTD., Suwon-Si (KR)

(72) Inventors: Jae Hoon PARK, Suwon-Si (KR); In Hyuk SONG, Suwon-Si (KR); Dong Soo SEO, Suwon-Si (KR); Ji Yeon OH, Suwon-Si (KR); Kee Ju UM, Suwon-Si (KR)

(73) Assignee: SAMSUNG ELECTRO-MECHANICS CO., LTD., Suwon-Si (KR)

(21) Appl. No.: 14/273,159

(22) Filed: May 8, 2014

(30) Foreign Application Priority Data
Dec. 27, 2013 (KR) 10-2013-0165428

(51) Int. Cl. H01L 29/739; H01L 29/10; H01L 29/06

(52) U.S. Cl. CPC H01L 29/7397; H01L 29/0619; H01L 29/1095

(57) ABSTRACT

A power semiconductor device may include a first semiconductor region having a first conductivity type; a second semiconductor region having a second conductivity type and formed in an upper portion of the first semiconductor region; a third semiconductor region having a first conductivity type and formed in an upper portion of the second semiconductor region; and a trench gate formed by penetrating from the third semiconductor region to the first semiconductor region. A portion of at least one of the first semiconductor region, the second semiconductor region, and the third semiconductor region may include a device protection material of which a conduction band has a main state and a satellite state in an E-k diagram, and a curvature of the device protection material in the satellite state may be lower than a curvature thereof in the main state in the E-k diagram.

### CROSS-REFERENCE TO RELATED APPLICATION

This application claims the benefit of Korean Patent Application No. 10-2013-0165428 filed on Dec. 27, 2013, with the Korean Intellectual Property Office, the disclosure of which is incorporated herein by reference.

### BACKGROUND

The present disclosure relates to a power semiconductor device having improved reliability.

An insulated gate bipolar transistor (IGBT) is a transistor manufactured to have bipolarity by forming a gate using a metal oxide semiconductor (MOS) and forming a p-type collector layer on a rear surface thereof.

Since power metal oxide semiconductor field effect transistors (MOSFET) were developed in the related art, these transistors have been used in fields requiring high speed switching characteristics.

However, due to inherent structural limitations of MOSFETs, bipolar transistors, thyristors, gate turn-off (GTO) thyristors, and the like, have been used in fields requiring the application of high levels of voltage thereto.

Since IGBTs have low forward loss and rapid switching speed characteristics, the application of the IGBT has increased in fields to which existing thyristors, bipolar transistors, MOSFETs and the like may not be applied.

An operational principle of an IGBT will hereinafter be described. In the case in which an IGBT is turned on, when a voltage applied to an anode is higher than a voltage applied to a cathode and a voltage higher than a threshold voltage of the IGBT is applied to a gate electrode, a polarity of a surface of a p-type well layer positioned at a lower end of the gate electrode may be inverted, such that an n-type channel may be formed.

An electron current injected into adrift region though the channel induces the injection of a hole current from a high-concentration p-type collector layer positioned in a lower portion of the IGBT, similar to a base current of the bipolar transistor.

Due to the injection of these minority carriers at a high concentration, a process of conductivity modulation, in which conductivity in the drift region increases by several tens to several hundreds of times, occurs.

Unlike the MOSFET, in the IGBT, a level of a resistance component in the drift region may be greatly reduced due to the process of conductivity modulation. Therefore, the IGBT allows very high levels of voltage to be applied thereto.

However, the IGBT may operate as a parasitic thyristor, due to structural characteristics thereof.

In the case in which the parasitic thyristor is operated, a very high level of current may flow therein. As a result, a large amount of heat may be generated, thereby harming or even destroying the IGBT.

A phenomenon in which the IGBT is destroyed due to the parasitic thyristor operating therein is referred to as latch-up.

In order to improve device reliability, a method allowing for devices to be robust against latch-up has been demanded.

The following Related Art Document (Patent Document 1) relates to a flat type insulated-gate bipolar transistor.

Patent Document 1 is characterized by a technology of preventing current flow in a thyristor structure after a positive voltage is applied to an IGBT by forming a buried oxide film on a lower portion of a p-base region to thereby prevent latch-up occurring in the IGBT.

However, Patent Document 1 does not disclose the manufacturing of a power semiconductor device using a device protection material having a main state and a satellite state in an E-k diagram.

### RELATED ART DOCUMENT

(Patent Document 1) Korean Patent Laid-Open Publication No. 2010-0016709

### SUMMARY

An aspect of the present disclosure may provide a power semiconductor device having improved reliability through preventing the destruction of the device caused by short circuits or latch-up.

According to an aspect of the present disclosure, a power semiconductor device may include: a first semiconductor region having a first conductivity type; a second semiconductor region having a second conductivity type and formed in an upper portion of the first semiconductor region; a third semiconductor region having a first conductivity type and formed in an upper portion of the second semiconductor region; and a trench gate formed by penetrating from the third semiconductor region to the first semiconductor region, wherein a portion of at least one of the first semiconductor region, the second semiconductor region, and the third semiconductor region may be formed of a device protection material of which a conduction band has a main state and a satellite state in an E-k diagram, and a curvature of the device protection material in the satellite state may be lower than a curvature thereof in the main state in the E-k diagram.

The device protection material may have an increase in an effective electron mass by transitioning electrons from the main state to the satellite state due to an increase in lattice temperature when latch-up occurs.

The device protection material may have lower ground energy in the main state than ground energy in the satellite state in the E-k diagram.

The second semiconductor region may be formed of the device protection material.

The first semiconductor region may be formed of the device protection material.

The third semiconductor region may be formed of the device protection material.

The power semiconductor device may further include a channel formed in a region in which the second semiconductor region and the trench gate contact when current is applied thereto, wherein the region in which the channel is formed may be formed of the device protection material.

The device protection material may have direct semiconductor properties in the E-k diagram.

The device protection material may have indirect semiconductor properties in the E-k diagram.

According to another aspect of the present disclosure, a power semiconductor device may include: a first semiconductor region having a first conductivity type; a second semiconductor region having a second conductivity type and formed in an upper portion of the first semiconductor region; a third semiconductor region having a first conductivity type and formed in an upper portion of the second semiconductor region; and a gate formed on the second semiconductor region, wherein a portion of at least one of the first semiconductor region, the second semiconductor region, and the third semiconductor region may be formed of a device protection material of which a conduction band has a main state and a satellite state in an E-k diagram, and a curvature of the device protection material in the satellite state may be lower than a curvature thereof in the main state in the E-k diagram.

The device protection material may have an increase in effective electron mass by transitioning electrons from the main state to the satellite state due to an increase in lattice temperature when latch-up occurs.

The device protection material may have lower ground energy in the main state than ground energy in the satellite state in the E-k diagram.

The second semiconductor region may be formed of the device protection material.

The first semiconductor region may be formed of the device protection material.

The third semiconductor region may be formed of the device protection material.

The power semiconductor device may further include a channel formed in a region in which the second semiconductor region and the gate contact when current is applied thereto, wherein the region in which the channel is formed may be formed of the device protection material.

The device protection material may have direct semiconductor properties in the E-k diagram.

The device protection material may have indirect semiconductor properties in the E-k diagram.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 shows a schematic cross-sectional view of a power semiconductor device according to an exemplary embodiment of the present disclosure;

FIGS. 2 and 3 schematically show E-k diagrams of a device protection material;

FIGS. 4 through 6 show schematic cross-sectional views of a power semiconductor device according to an exemplary embodiment of the present disclosure; and

FIGS. 7 through 10 show schematic cross-sectional views of a power semiconductor device according to another exemplary embodiment of the present disclosure.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

A power switch may be configured as any one of a power metal oxide semiconductor field effect transistor (MOSFET), an insulated gate bipolar transistor (IGBT), a thyristor, and devices similar thereto. Most of the new technologies disclosed herein will be described based on the IGBT. However, several exemplary embodiments of the present disclosure are not limited to the IGBT. The present inventive concept may also be applied to other types of power switch technology including power MOSFETs and several types of thyristors. Further, several exemplary embodiments of the present disclosure will be described as including specific p-type and n-type regions. However, conductivity types of several regions disclosed herein may be similarly applied to devices having conductivity types opposite thereto.

In addition, an n-type or a p-type used herein may be defined as a first conductivity type or a second conductivity type. Meanwhile, the first and second conductivity types are different types of conductivity.

In general, ‘+’ refers to a state in which a region is heavily doped and ‘−’ refers to a state in which a region is lightly doped.

For clarification, the first conductivity type will be referred to as an n-type and the second conductivity type will be referred to as a p-type, but the present disclosure is not limited thereto.

In addition, a first semiconductor region represents adrift region, a second semiconductor region represents a well region, and a third semiconductor region represents an emitter region, but the present disclosure is not limited thereto.

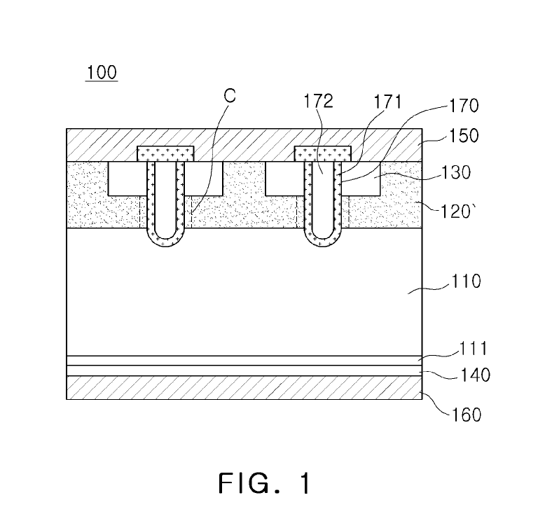

FIG. 1 shows a schematic cross-sectional view of a power semiconductor device according to an exemplary embodiment of the present disclosure.

A power semiconductor device 100 according to an exemplary embodiment of the present disclosure may include a drift region 110, a well region 120′, an emitter region 130, and a collector region 140.

The drift region 110 may be formed by implanting n-type impurities at a low concentration.

Therefore, the drift region 110 may be relatively thick in order to maintain a breakdown voltage of the power semiconductor device.

The drift region 110 may further include a buffer region 111 formed in a lower portion thereof.

The buffer region 111 may be formed by implanting n-type impurities into the lower portion of the drift region 110.

The buffer region 111 may serve to block extension of a depletion region of the power semiconductor device, thereby assisting in maintaining a breakdown voltage of the power semiconductor device.

Therefore, in the case in which the buffer region 111 is formed, a thickness of the drift region 110 may be decreased, whereby the power semiconductor device may be miniaturized.

The well region 120′ may be formed by implanting p-type impurities into an upper portion of the drift region 110.

The well region 120′ may have a p-conductivity type to form a p-n junction with the drift region 110.

The emitter region 130 may be formed by implanting n-type impurities at a high concentration into an upper portion of the well region 120′.

A trench gate 170 may be formed to extend from the emitter region 130 to the drift region 110 through the well region 120′.

That is, the trench gate 170 may penetrate from the emitter region 130 into a portion of the drift region 110.

The trench gate 170 may have a gate insulating layer 171 formed in a region in which it contacts the drift region 110, the well region 120′, and the emitter region 130.

The gate insulating layer 171 may be formed of a silicon oxide (SiO₂), but is not limited thereto.

The trench gate 170 may be filled with a conductive material 172.

The conductive material 172 may be a polysilicon (poly-Si) or a metal, but is not limited thereto.

The conductive material 172 may be electrically connected to a gate electrode (not shown) to control an operation of the power semiconductor device 100 according to the exemplary embodiment of the present disclosure.

In the case in which a positive voltage is applied to the conductive material 172, a channel C may be formed in the well region 120′.

In detail, in the case in which the positive voltage is applied to the conductive material 172, electrons present in the well region 120′ may be drawn toward the trench gate 170 and be collected around the trench gate 170, thereby forming the channel C.

That is, electrons and holes may be recombined with each other due to a p-n junction, such that the trench gate 170 draws the electrons toward a depletion region in which carriers are not present to thereby form the channel C, whereby a current may flow through the channel.

The collector region 110 may be formed by implanting p-type impurities into a lower portion of drift region 110 or the buffer region 111.

In the case in which the power semiconductor device is an IGBT, the collector region 110 may provide holes to the power semiconductor device.

Due to injection of the holes, which are minority carriers, at a high concentration, a conductivity modulation in which conductivity in the drift region is increased by several tens to several hundreds of times occurs.

A resistance component in the drift region 110 becomes very small due to the conductivity modulation. Therefore, the power semiconductor device may be used at a very high voltage.

In the case in which the power semiconductor device is an MOSFET, the collector region 140 may have an n-conductivity type.

An emitter metal layer 150 may be formed on exposed upper surfaces of the emitter region 130 and the well region 120′, and a collector metal layer 160 may be formed on a lower surface of the collector region 140.

Referring to FIG. 1, the well region 120′ of the power semiconductor device 100 according to the exemplary embodiment of the present disclosure may be formed of a device protection material.

In FIG. 1, components formed of the device protection material are depicted as being dotted.

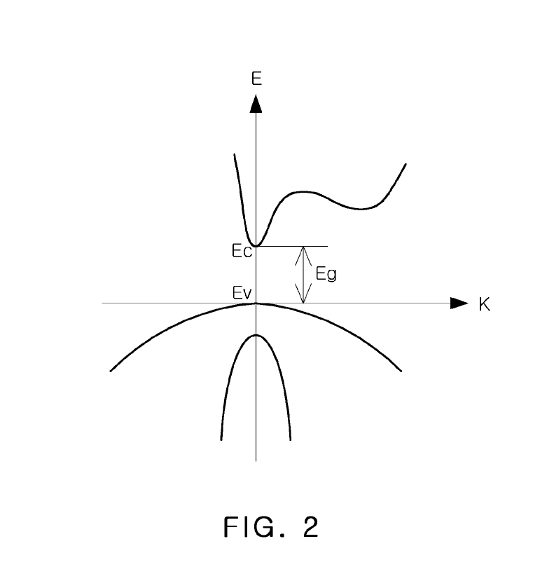

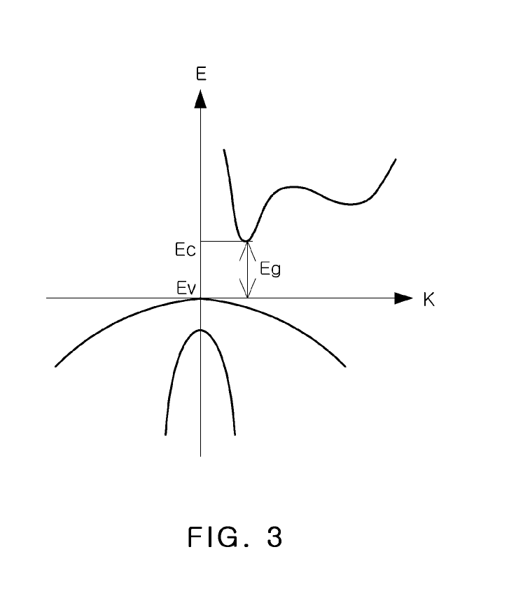

The device protection material will be described in detail with reference to FIGS. 2 and 3.

FIGS. 2 and 3 schematically show E-k diagrams of a device protection material.

Referring to FIGS. 2 and 3, a conduction band of the device protection material may have a main state and a satellite state in the E-k diagram.

Therefore, when a temperature is changed, electrons in the device protection material may be present in the main state or the satellite state, accordingly.

As shown in FIGS. 2 and 3, it may be seen that a curvature of the device protection material in the satellite state is very smaller than a curvature thereof in the main state.

As seen in the following Equation 1, an effective electron mass m* is proportional to a reciprocal of a curvature of the E-k diagram. Here, the curvature of the E-k diagram may be a second derivative value.

$${m}^{*} ∝ \frac{1}{\frac{{\partial }^{2} E}{\partial {k}^{2}}} \qquad [ Equation 1 ]$$

That is, the second derivative value of the E-k diagram is inversely proportional to the effective electron mass and as the curvature of the E-k diagram is increased, the second derivative value may become large.

As seen in FIGS. 2 and 3, since the curvature of the device protection material in the satellite state is significantly smaller than the curvature thereof in the main state, the effective electron mass may be increased when the electrons are transitioned to the satellite state.

In the case in which the effective electron mass is increased, electron mobility may be decreased.

In a case of a material used in an existing IGBT according to the related art, within a typical operating range, electrons are mainly present in a main state in a conduction band and are hardly present in a satellite state.

In this case, even in the case in which an excessive amount of current flows and a high level of heat is generated when short circuit or latch-up occurs in the IGBT, the effective electron mass is hardly changed.

However, since the power semiconductor device 100 according to the exemplary embodiment of the present disclosure has the well region 120′ formed of the device protection material, the effective electron mass may be significantly increased when a high level of heat is generated in the device.

Since the electron mobility is decreased in the case in which the effective electron mass is increased, an increase in the amount of current due to short circuits or latch-up is decreased, whereby the destruction of the device may be prevented and device reliability may be improved.

Since a ground energy level in the main state is lower than a ground energy level in the satellite state, in the case in which the power semiconductor device 100 is operated normally, the effective electron mass is low, whereby the electron mobility may be high and the current may flow smoothly.

Therefore, in the power semiconductor device 100 according to the exemplary embodiment of the present disclosure, in the case in which the short circuit or the latch-up does not occur, the current flows smoothly and in the case in which the short circuit or the latch-up occurs, a flow of current is decreased, whereby device reliability may be improved.

In the case in which an energy barrier transitioning from the main state to the satellite state is too high, it is difficult to expect an effect of an improvement in device reliability.

Therefore, the device protection material may be a material having an energy barrier allowing the electrons to be transitioned from the main state to the satellite state by lattice heating due to the latch-up.

For example, the device protection material may have the energy barrier in which the electrons are transitioned from the main state to the satellite state to some extent that the transitioning of the electrons is achieved at about 800° C.

As seen in FIGS. 2 and 3, in the case in which the curvature of the device protection material in the satellite state is lower than the curvature thereof in the main state regardless of whether or not the device protection material has direct semiconductor properties or indirect semiconductor properties in the E-k diagram, such a device protection material may be used.

Specifically, the device protection material may be at least one selected from a group consisting of InP, InSb, InAs, GaAs, and AlGaAs, but is not limited thereto. A material having the E-k structure (e.g., conduction structure) as described above may be used.

The power semiconductor device 100 according to the exemplary embodiment of the present disclosure has the well region 120′ formed of the device protection material, such that the current flow in the well region 120′ may be decreased in the case in which the short circuit or the latch-up occurs in the device, thereby protecting the device.

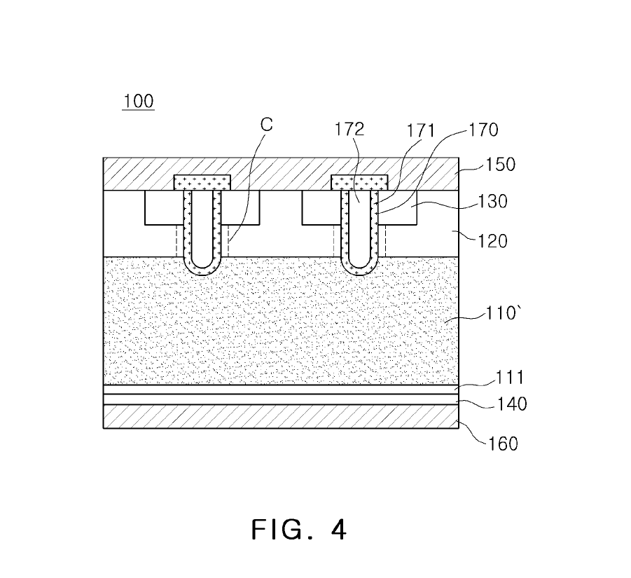

FIG. 4 shows a schematic cross-sectional view of a power semiconductor device having a drift region formed of a device protection material according to an exemplary embodiment of the present disclosure.

As shown in FIG. 4, a drift region 110′ of the power semiconductor device 100 according to this exemplary embodiment of the present disclosure may be formed of a device protection material.

The drift region 110′ may occupy a relatively large portion of the power semiconductor device 100 as compared with the other regions.

Therefore, in the case in which the drift region 110′ is formed of the device protection material, reliability may be significantly improved as compared with other exemplary embodiments.

The entirety of the drift region 110′ may be formed of the device protection material, but the present disclosure is not limited thereto.

For example, only a portion of the drift region 110′ may be formed of the device protection material.

That is, only a portion of the drift region 110′ may be formed of the device protection material using an epitaxial method.

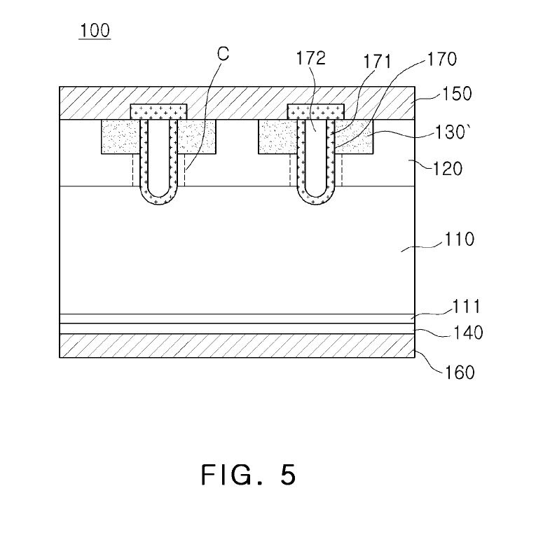

FIG. 5 shows a schematic cross-sectional view of a power semiconductor device having an emitter region formed of a device protection material according to an exemplary embodiment of the present disclosure.

As shown in FIG. 5, an emitter region 130′ of the power semiconductor device 100 according to this exemplary embodiment of the present disclosure may be formed of a device protection material.

Since the emitter region 130′ is formed by implanting n-type impurities at a high concentration, it may have a relatively large number of electrons as compared with other regions.

Therefore, in the case in which the emitter region 130′ is formed of the device protection region, it may significantly affect device reliability.

The entirety of the emitter region 130′ may be formed of the device protection material, but the present disclosure is not limited thereto.

For example, only a portion of the emitter region 130′ may be formed of the device protection material.

That is, only a portion of the emitter region 130′ may be formed of the device protection material using an epitaxial method.

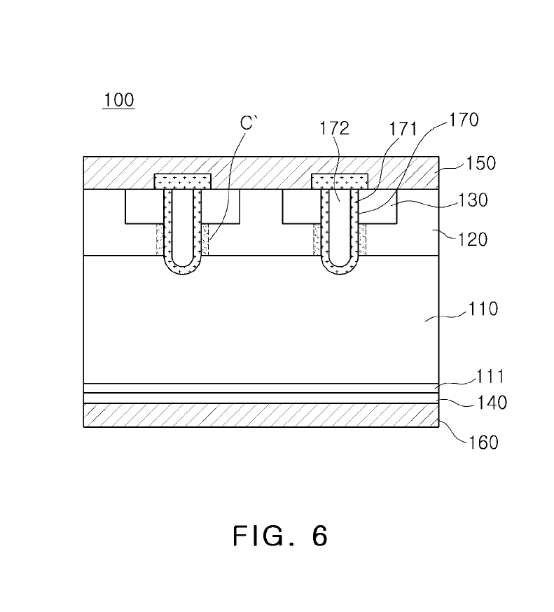

FIG. 6 shows a schematic cross-sectional view of a power semiconductor device having a channel formed of a device protection material according to an exemplary embodiment of the present disclosure.

As shown in FIG. 6, a channel C′ of the power semiconductor device 100 according to this exemplary embodiment of the present disclosure may be formed of a device protection material.

The channel C′ may refer to a region formed when a positive voltage is applied to the trench gate 170.

Particularly, in the case in which short circuits occur, an excessive amount of current flows through the channel C′. Therefore, device reliability may be efficiently improved by forming the channel C′ using the device protection material.

The entirety of the channel C′ may be formed of the device protection material, but the present disclosure is not limited thereto.

For example, only a portion of the channel C′ may be formed of the device protection material.

That is, only a portion of the channel C′ may be formed of the device protection material using an epitaxial method.

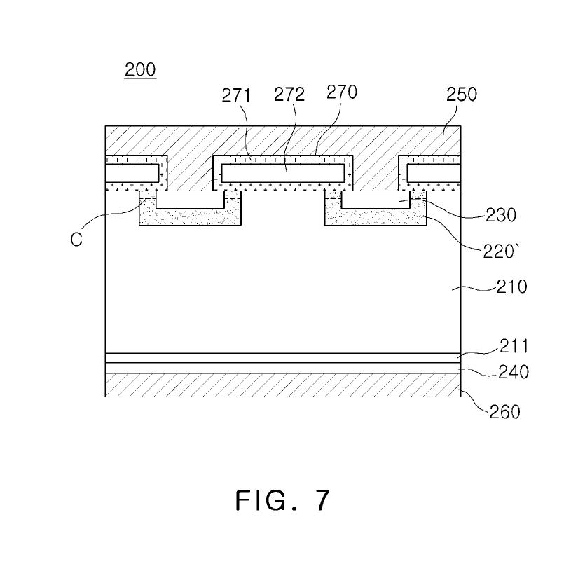

FIG. 7 shows a schematic cross-sectional view of a power semiconductor device having a well region formed of a device protection material according to another exemplary embodiment of the present disclosure.

A power semiconductor device 200 according to another exemplary embodiment of the present disclosure may include a drift region 210, a well region 220′ having a second conductivity type and formed in an upper portion of the drift region 210, an emitter region 230 having a first conductivity type and formed in an upper portion of the well region 220′, and a gate 270 formed above the well region 220.

The gate 270 may be disposed above the well region 220′ and may be formed by forming a gate insulating layer 271 on the well region 220′ and forming a conductive material 272 thereon.

In the case in which a positive voltage is applied to the conductive material 272, a channel C may be formed in the well region 220′.

In detail, in the case in which the positive voltage is applied to the conductive material 272, electrons present in the well region 220′ may be drawn toward the gate 270 and be collected around the gate 270, thereby forming the channel C.

That is, electrons and holes may be recombined with each other due to a p-n junction, such that the gate 270 draws the electrons toward a depletion region in which carriers are not present to thereby form the channel C, whereby a current may flow therethrough.

The drift region 210 may further include a buffer region 211 formed in a lower portion thereof.

The buffer region 211 may be formed by implanting n-type impurities into the lower portion of the drift region 210.

The buffer region 211 may serve to block extension of a depletion region of the power semiconductor device, thereby assisting in maintaining a breakdown voltage of the power semiconductor device.

Therefore, in the case in which the buffer region 211 is formed, a thickness of the drift region 210 may be decreased, whereby the power semiconductor device may be miniaturized.

A collector region 240 may be formed by implanting p-type impurities into the lower portion of the drift region 210 or the buffer region 211.

An emitter metal layer 250 may be formed on upper surfaces of the drift region 210, the well region 220′, and the emitter region 230.

A collector metal layer 260 may be formed on a lower surface of the collector region 240.

Since the power semiconductor device 200 according to the exemplary embodiment of the present disclosure has the well region 220′ formed of a device protection material, an effective electron mass may be significantly increased when a high level of heat is generated from the device.

Since electron mobility is decreased in the case in which the effective electron mass is increased, an increase in the amount of current due to short circuits or latch-up is decreased, whereby the destruction of the device may be prevented and device reliability may be improved.

The entirety of the well region 220′ may be formed of a device protection material, but the present disclosure is not limited thereto.

For example, only a portion of the well region 220′ may be formed of the device protection material.

That is, only a portion of the well region 220′ may be formed of the device protection material using an epitaxial method.

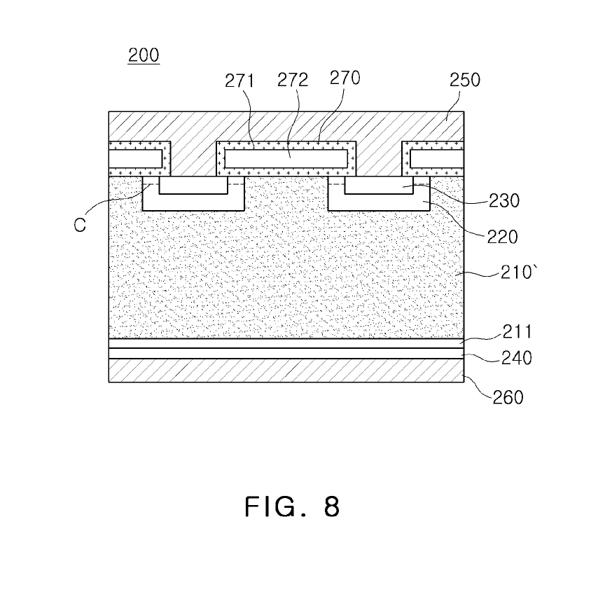

FIG. 8 shows a schematic cross-sectional view of a power semiconductor device having a drift region formed of a device protection material according to another exemplary embodiment of the present disclosure.

As shown in FIG. 8, a drift region 210′ of the power semiconductor device 200 according to this exemplary embodiment of the present disclosure may be formed of a device protection material.

The drift region 210′ may occupy a relatively large portion of the power semiconductor device 200 as compared with the other regions.

Therefore, in the case in which the drift region 210′ is formed of the device protection material, reliability may be significantly improved as compared with other exemplary embodiments.

The entirety of the drift region 210′ may be formed of the device protection material, but the present disclosure is not limited thereto.

For example, only a portion of the drift region 210′ may be formed of the device protection material.

That is, only a portion of the drift region 210′ may be formed of the device protection material using an epitaxial method.

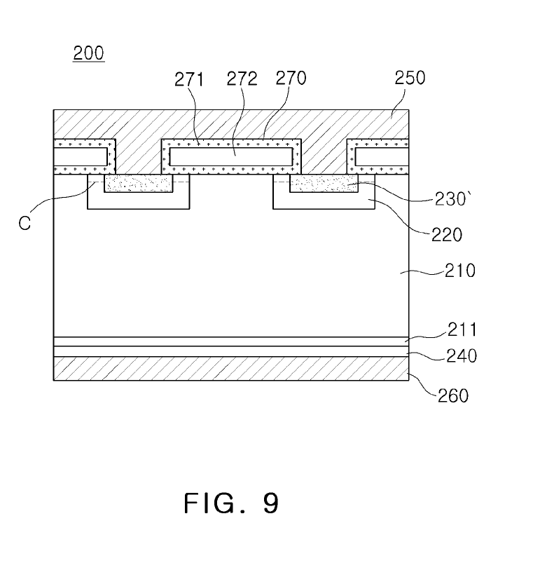

FIG. 9 shows a schematic cross-sectional view of a power semiconductor device having an emitter region formed of a device protection material according to another exemplary embodiment of the present disclosure.

As shown in FIG. 9, an emitter region 230′ of the power semiconductor device 200 according to this exemplary embodiment of the present disclosure may be formed of a device protection material.

Since the emitter region 230′ is formed by implanting n-type impurities at a high concentration, it may have a relatively large number of electrons present therein as compared with the other regions.

Therefore, in the case in which the emitter region 230′ is formed of the device protection region, it may significantly affect device reliability.

The entirety of the emitter region 230′ may be formed of the device protection material, but the present disclosure is not limited thereto.

For example, only a portion of the emitter region 230′ may be formed of the device protection material.

That is, only a portion of the emitter region 230′ may be formed of the device protection material using an epitaxial method.

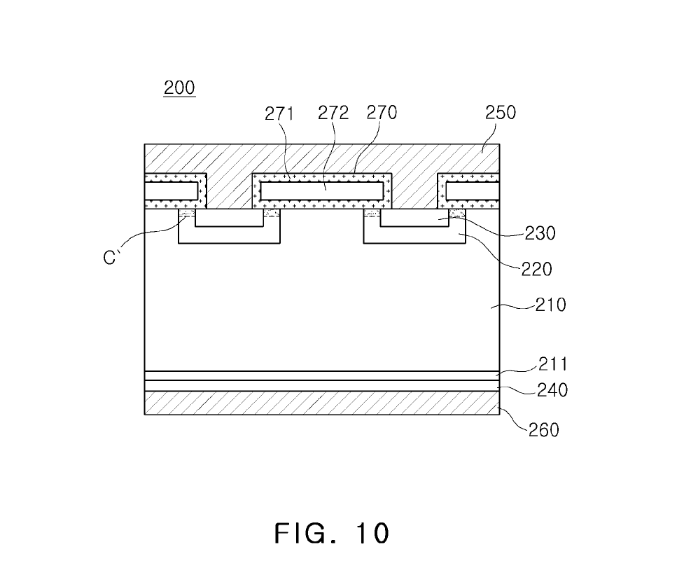

FIG. 10 shows a schematic cross-sectional view of a power semiconductor device having a channel formed of a device protection material according to another exemplary embodiment of the present disclosure.

As shown in FIG. 10, a channel C′ of the power semiconductor device 200 according to this exemplary embodiment of the present disclosure may be formed of a device protection material.

The channel C′ may refer to a region formed when a positive voltage is applied to the gate 270.

Particularly, in the case in which short circuits occur, since an excessive amount of current flows through the channel C′, device reliability may be efficiently improved by forming the channel C′ using the device protection material.

The entirety of the channel C′ may be formed of the device protection material, but the present disclosure is not limited thereto.

For example, only a portion of the channel C′ may be formed of the device protection material.

That is, only a portion of the channel C′ may be formed of the device protection material using an epitaxial method.

As set forth above, according to exemplary embodiments of the present disclosure, a portion or all of regions of the power semiconductor device may be formed of a device protection material having a main state and a satellite state in an E-k diagram. When latch-up occurs and heat is generated in the device, electrons may be transitioned to the satellite state, thereby decreasing electron mobility.

By decreasing electron mobility, when the short circuit or the latch-up occurs, the flow of current may be decreased, whereby reliability of the power semiconductor device may be improved.

While exemplary embodiments have been shown and described above, it will be apparent to those skilled in the art that modifications and variations could be made without departing from the spirit and scope of the present disclosure as defined by the appended claims.

What is claimed is:

1. A power semiconductor device, comprising:
a first semiconductor region having a first conductivity type;
a second semiconductor region having a second conductivity type and formed in an upper portion of the first semiconductor region;
a third semiconductor region having a first conductivity type and formed in an upper portion of the second semiconductor region; and
a trench gate formed by penetrating from the third semiconductor region to the first semiconductor region,
wherein a portion of at least one of the first semiconductor region, the second semiconductor region, and the third semiconductor region includes a device protection material of which a conduction band has a main state and a satellite state in an E-k diagram, and
a curvature of the device protection material in the satellite state is lower than a curvature thereof in the main state in the E-k diagram.

2. The power semiconductor device of claim 1, wherein the device protection material is a material having an energy barrier allowing electrons to be transitioned from the main state to the satellite state by lattice heating due to latch-up.

3. The power semiconductor device of claim 1, wherein the device protection material has lower ground energy in the main state than ground energy in the satellite state in the E-k diagram.

4. The power semiconductor device of claim 1, wherein the second semiconductor region comprises the device protection material.

5. The power semiconductor device of claim 1, wherein the first semiconductor region comprises the device protection material.

6. The power semiconductor device of claim 1, wherein the third semiconductor region comprises the device protection material.

7. The power semiconductor device of claim 1, further comprising a channel formed in a region in which the second semiconductor region and the trench gate contact when current is applied thereto,
wherein the region in which the channel comprises the device protection material.

8. The power semiconductor device of claim 1, wherein the device protection material has direct semiconductor properties in the E-k diagram.

9. The power semiconductor device of claim 1, wherein the device protection material has indirect semiconductor properties in the E-k diagram.

10. The power semiconductor device of claim 1, wherein the device protection material has an effective electron mass increased when latch-up occurs.

11. A power semiconductor device, comprising:
a first semiconductor region having a first conductivity type;
a second semiconductor region having a second conductivity type and formed in an upper portion of the first semiconductor region;
a third semiconductor region having a first conductivity type and formed in an upper portion of the second semiconductor region; and
a gate formed on the second semiconductor region,
wherein a portion of at least one of the first semiconductor region, the second semiconductor region, and the third semiconductor region includes a device protection material of which a conduction band has a main state and a satellite state in an E-k diagram, and
a curvature of the device protection material in the satellite state is lower than a curvature thereof in the main state in the E-k diagram.

12. The power semiconductor device of claim 11, wherein the device protection material is a material having an energy barrier allowing electrons to be transitioned from the main state to the satellite state by lattice heating due to latch-up.

13. The power semiconductor device of claim 11, wherein the device protection material has lower ground energy in the main state than ground energy in the satellite state in the E-k diagram.

14. The power semiconductor device of claim 11, wherein the second semiconductor region comprises the device protection material.

15. The power semiconductor device of claim 11, wherein the first semiconductor region comprises the device protection material.

16. The power semiconductor device of claim 11, wherein the third semiconductor region comprises the device protection material.

17. The power semiconductor device of claim 11, further comprising a channel formed in a region in which the second semiconductor region and the gate contact when current is applied thereto,
wherein the region in which the channel comprises the device protection material.

18. The power semiconductor device of claim 11, wherein the device protection material has direct semiconductor properties in the E-k diagram.

19. The power semiconductor device of claim 11, wherein the device protection material has indirect semiconductor properties in the E-k diagram.

20. The power semiconductor device of claim 11, wherein the device protection material has an effective electron mass increased when latch-up occurs.
